(19) United States
(12) Patent Application Publication
(10) Pub. No.: US 2020/0343391 A1
(43) Pub. Date: Oct. 29, 2020

(54) SOLAR CELL AND MANUFACTURING METHOD THEREOF

(71) Applicant: LG ELECTRONICS INC., Seoul (KR)

(72) Inventors: Jaewoo CHOI, Seoul (KR); Hanjong YU, Seoul (KR); Hyoungkyun KONG, Seoul (KR)

(73) Assignee: LG ELECTRONICS INC., Seoul (KR)

(21) Appl. No.: 16/837,755

(22) Filed: Apr. 1, 2020

(30) Foreign Application Priority Data
Apr. 25, 2019 (KR) 10-2019-0048783

(51) Int. Cl. H01L 31/0216

(52) U.S. Cl. CPC H01L 31/02168; H01L 31/022441; H01L 31/02164

(57) ABSTRACT

Provided are a solar cell and a manufacturing method thereof. The solar cell includes a semiconductor substrate, a conductivity type region positioned at or on the semiconductor substrate and including impurities, an electrode electrically connected to the conductivity type region, and an insulating layer positioned on at least one of one surface or the opposite surface of the semiconductor substrate, wherein the insulating layer includes: a first layer positioned on the semiconductor substrate and including an oxygen (O)-based material, a second layer positioned on the first layer, an anti-reflective layer positioned on the second layer, and a third layer positioned on the anti-reflective layer and including a silicon (Si)-based material and a carbon (C)-based material, wherein a bandgap of the first layer is formed to be higher than a bandgap of each of the second layer, the anti-reflective layer, and the third layer.

### CROSS-REFERENCE TO RELATED APPLICATION

This application claims priority to and the benefit of Korean Patent Application No. 10-2019-0048783 filed in the Korean Intellectual Property Office on Apr. 25, 2019.

### BACKGROUND OF THE INVENTION

### Field of the invention

The present disclosure relates to a solar cell and a method of manufacturing the same, and more particularly, to a solar cell in which a structure of an insulating layer positioned on a surface on which light is incident is improved, and a method of manufacturing the same.

### Related Art

Solar cells produce electric power by generating carriers in a semiconductor region upon receiving the light of the sun from the outside.

Such solar cells include a conventional type solar cell in which electrodes having different polarities are provided on a front surface and a rear surface of a semiconductor substrate and a back contact type solar cell in which electrodes having different polarities are provided on a surface opposite to a surface on which light is incident.

Since the solar cells are configured to generate electric power upon receiving light from the outside, transmittance of incident light directly affects efficiency of the solar cells, and the efficiency of the solar cells is directly related to energy production.

Therefore, many studies have been conducted to reduce light transmittance on the incident surface of the solar cells, and in addition, many studies have been conducted to increase an open-circuit voltage (Voc) of solar cells, which is another factor affecting energy generation.

As an example, U.S. Pat. No. 8,198,528, a related art document, discloses a solar cell including an insulating layer formed of a dual-layer of a passivation layer and an anti-reflective layer (SiNx).

However, in a solar cell module having a plurality of solar cells, moisture may penetrate into the module through a sealing material positioned between the solar cell and a transparent substrate. When moisture penetrates into the module, acetic acid is produced and the produced acetic acid may adversely affect the solar cell.

For example, an anti-reflective layer formed of an SiNx material provided in the insulating layer disclosed in the above patent may be etched by the acetic acid produced in the sealing material such as an ethylene-vinyl acetate copolymer (EVA), and damp heat may degrade reliability of the solar cell module.

In addition, when a surface of the anti-reflective layer is etched by the acetic acid, transmittance of the anti-reflective layer (SiNx) is lowered to make light loss, thereby degrading efficiency of the solar cell module.

### SUMMARY OF THE INVENTION

The present disclosure provides a solar cell and a method of manufacturing the same.

Specifically, the present disclosure provides a solar cell capable of blocking an ultraviolet (UV) ray, preventing an insulating layer from being etched by an acetic acid, and preventing an open circuit voltage (Voc) and a short circuit current (Isc) of the solar cell from being lowered due to the UV ray by improving a material of the outermost layer in contact with a sealing material such as an ethylene-vinyl acetate copolymer (EVA) in an insulating layer positioned on a surface on which light is incident, and a method of manufacturing the same.

In an aspect, a solar cell includes: a semiconductor substrate; a conductivity type region positioned at or on the semiconductor substrate and including impurities; an electrode electrically connected to the conductivity type region; and an insulating layer positioned on at least one of one surface or the opposite surface of the semiconductor substrate, wherein the insulating layer includes: a first layer positioned on the semiconductor substrate and including an oxygen (O)-based material; a second layer positioned on the first layer; an anti-reflective layer positioned on the second layer; and a third layer positioned on the anti-reflective layer and including a silicon (Si)-based material and a carbon (C)-based material, wherein a bandgap of the first layer is formed to be higher than a bandgap of each of the second layer, the anti-reflective layer, and the third layer.

The conductivity type region may be positioned on at least one of the one surface and the opposite surface of the semiconductor substrate, and the first layer may be positioned on the conductivity type region.

The bandgap of the first layer may be 8 eV to 10 eV within a range higher than the bandgap of each of the second layer, the anti-reflective layer, and the third layer.

The first layer may include at least one of SiOx, SiO₂, SiOxNy, AlxOy, TixOy, or HfOx.

The second layer may contain hydrogen, and a hydrogen content of the second layer may be higher than a hydrogen content of each of the first layer, the anti-reflective layer, and the third layer.

The second layer may include a silicon (Si)-based material and may further include a nitrogen (N)-based material or an oxygen (O)-based material. As an example, the second layer may include SiNx or AlxOy.

The anti-reflective layer may include a silicon (Si)-based material and may further include an oxygen (O)-based or nitrogen (N)-based material. For example, the anti-reflective layer may include at least one of materials among SiOx, SiOxNy, and SixNy.

Transmittance of the anti-reflective layer for a wavelength band of 400 nm to 1100 nm may be higher than transmittance of the second layer for the wavelength band and lower than transmittance of the first layer for the wavelength band.

The third layer may include at least one of materials among SixOyCz, SixCy, and SixCyNz.

A refractive index of the third layer may be higher than a refractive index of the second layer and a refractive index of the first layer. As an example, the refractive index of the third layer may be 2.2 or greater.

The refractive index of the second layer may be higher than the refractive index of the anti-reflective layer and the refractive index of the first layer. For example, the refractive index of the second layer may be 1.9 to 2.2.

The refractive index of the anti-reflective layer may be 1.9 or less.

A thickness of the second layer may be greater than a thickness of each of the first layer, the anti-reflective layer, and the third layer. As an example, the thickness of the second layer may be 50 nm or less.

The thickness of the third layer may be smaller than the thickness of the first layer and the thickness of the anti-reflective layer. For example, the thickness of the third layer may be 20 nm or less in a range smaller than the thickness of the first layer and the thickness of the anti-reflective layer, and the thickness of the first layer may be 8 nm to 25 nm in a range larger than the thickness of the third layer.

The first layer may include a high density layer positioned adjacent to the substrate and having a first density and a low density layer positioned on the high density layer and having a second density lower than the first density.

The high density layer may include SiO₂, the low density layer may include SiOxNy, a thickness of the high density layer may be 5 nm to 10 nm, and a thickness of the low density layer may be 2 nm to 15 nm.

The first layer in the insulating layer may be positioned closest to the semiconductor substrate, and the third layer may configure the outermost layer in the insulating layer.

The conductivity type region may include first and second conductivity type regions positioned adjacent to a rear surface of the semiconductor substrate and having different conductivity types, respectively, and the insulating layer may be positioned on a front surface of the semiconductor substrate.

In another aspect, a method of manufacturing a solar cell includes: forming a first layer including an oxygen (O)-based material on a semiconductor substrate; forming a second layer on the first layer; forming an anti-reflective layer on the second layer; and forming a third layer including a silicon (Si)-based material and a carbon (C)-based material on the anti-reflective layer.

The forming of the first layer may include: forming a high density layer on the semiconductor substrate using an oxidation method; and forming a low density layer having a lower density than the high density layer on the high density layer using plasma-enhanced chemical vapor deposition (PECVD).

Each of the third layer, the anti-reflective layer, and the second layer may be formed by PECVD.

### BRIEF DESCRIPTION OF THE DRAWINGS

FIG. 1 is a view illustrating an example of a back contact type solar cell including an insulating layer according to a first embodiment of the present disclosure.

FIG. 2 is a view illustrating an example of a conventional type solar cell including an insulating layer according to the first embodiment of the present disclosure.

FIG. 3 is a view specifically illustrating a structure of the insulating layer according to the first embodiment of the present disclosure in more detail.

FIG. 4 is a view illustrating a structure of an insulating layer according to a second embodiment of the present disclosure.

FIG. 5 is a view illustrating a comparison between a passivation effect of the insulating layer according to the first embodiment of the present disclosure and a passivation effect of the insulating layer according to the second embodiment of the present disclosure.

FIG. 6 is a view illustrating reflectivity of the insulating layer according to the second embodiment of the present disclosure.

FIG. 7 is a view illustrating output power and efficiency of a solar cell including an insulating layer according to the second embodiment of the present disclosure.

FIG. 8 is a view illustrating a method of manufacturing a solar cell according to an embodiment of the present disclosure.

### DESCRIPTION OF EMBODIMENTS

Hereinafter, embodiments will be described in detail with reference to the accompanying tables and drawings such that they can be easily practiced by those skilled in the art to which the present invention pertains. As those skilled in the art would realize, the described embodiments may be modified in various different ways, all without departing from the spirit or scope of the present invention. In the accompanying drawings, a portion irrelevant to description of the present invention will be omitted for clarity. Like reference numerals refer to like elements throughout.

Reference will now be made in detail to the preferred embodiments of the present invention, examples of which are illustrated in the accompanying drawings. The present invention may, however, be embodied in many alternate forms and should not be construed as limited to the embodiments set forth herein.

For simplicity and clarity of description, illustration of components not associated with the description is omitted in the drawings, and the same or extremely similar elements are denoted by the same reference numerals throughout the specification. In addition, the thickness, area, and the like of elements in the drawings may be expanded or contracted to aid in clear understanding of the elements, and the thickness, area, and the like of the present invention are not limited to the illustration of the drawings.

It will be further understood that the term “include” is used to specify that any one component includes the other component, this does not preclude the presence or addition of one or more other components unless otherwise stated. In addition, when an element, such as a layer, film, region, plate, and the like, is referred to as being formed “on” another element, it can be “directly on” the other element or be indirectly formed with intervening elements therebetween. On the other hand, when an element, such as a layer, film, region, plate, and the like, is referred to as being formed “directly on” another element, this means that no element is interposed therebetween.

In addition, when a thickness, width, or length of a specific component is equal to a thickness, width, or length of another specific component, this means that the thickness, width, or length of the other specific component is equal to the thickness, width, or length of the specific component within a process error range.

Therefore, when the process error range is 10%, the same thickness means that the thicknesses are the same within a 10% range. Hereinafter, a description will be given on the assumption that the process error range is 10%.

In addition, one surface or the opposite surface of the semiconductor substrate refers to a surface opposite to each other in the plane of the semiconductor substrate. Thus, as an example, when one surface of the semiconductor substrate is a front surface of the semiconductor substrate on which light is incident, the opposite surface of the semiconductor substrate refers to a rear surface of the semiconductor substrate. Alternatively, in contrast, when one surface of the semiconductor substrate is the rear surface of the semiconductor substrate, the opposite surface of the semiconductor substrate may refer to the front surface of the semiconductor substrate.

Hereinafter, for the purposes of description, it is assumed that one surface of the semiconductor substrate is the front surface of the semiconductor substrate and the opposite surface of the semiconductor substrate is the rear surface of the semiconductor substrate.

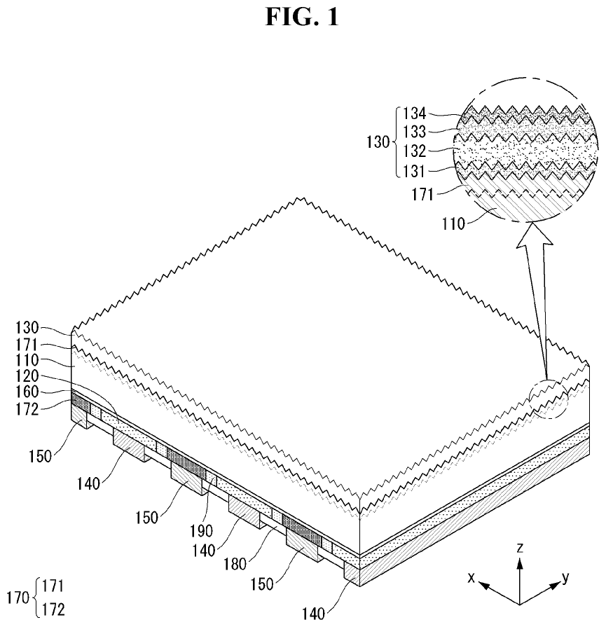

FIG. 1 is a view illustrating an example of a back contact type solar cell including an insulating layer 130 according to a first embodiment of the present disclosure.

As shown in FIG. 1, an example of a solar cell according to the present disclosure includes a semiconductor substrate 110, a control passivation layer 160, a first conductivity type region 170, and a second conductivity type region 120, an intrinsic semiconductor part 190, an insulating layer 130, a rear passivation layer 180, a plurality of first electrodes 140, and a plurality of second electrodes 150.

The semiconductor substrate 110 may be formed of one of single crystal silicon and polycrystalline silicon including a first conductivity type dopant or a second conductivity type dopant. For example, the semiconductor substrate 110 may be formed by doping a single crystal silicon wafer with a low concentration of the first conductivity type dopant or the second conductivity type dopant.

Here, the first conductivity type dopant may be either p-type or n-type dopant, and the second conductivity type dopant may be either n-type or p-type dopant. The first conductivity type dopant and the second conductivity type dopant have the mutually opposite conductivity types.

When the first conductivity type dopant is p-type of one of Group III elements such as boron (B), aluminum (Al), gallium (Ga), and indium (In), the second conductivity type dopant may be n-type of one of Group V elements such as phosphorus (P), arsenic (As), bismuth (Bi), and antimony (Sb).

Thus, as an example, one of the first and second conductivity type dopants may be boron B, and the other, that is, one of the second and first conductivity type dopants may be phosphorus (P).

The control passivation layer 160 may be disposed to be in direct contact with the entire rear surface of the semiconductor substrate 110 and may include a dielectric material.

The control passivation layer 160 may allow carriers generated in the semiconductor substrate 110 to pass therethrough and perform a passivation function on the rear surface of the semiconductor substrate 110. To this end, a thickness of the control passivation layer 160 may be formed between 0.5 nm and 2 nm.

As such, the control passivation layer 160 may be formed of a dielectric material including SiCx or SiOx having a strong durability even in a heat treatment process at 600° C. to 700° C.

The first conductivity type region 170 may be provided on a front surface or a rear surface of the semiconductor substrate 110 and may have the same conductivity type as that of the semiconductor substrate 110.

For example, the first conductivity type region 170 refers to a region in which a dopant of the same conductivity type as that of the semiconductor substrate 110 is doped at a higher concentration than a doping concentration of the semiconductor substrate 110.

For example, as illustrated in FIG. 1, the first conductivity type region 170 may include a front field part 171 and a rear field part 172.

The front field part 171 is provided on the entire surface of the semiconductor substrate 110, and the front surface field part 171 may have the same conductivity type dopant as the conductivity type of the semiconductor substrate at a concentration higher than the doping concentration of the semiconductor substrate 110.

For example, the front field part 171 may be formed by diffusing a conductivity type dopant inside the front surface of the semiconductor substrate 110 by a thermal diffusion method. Therefore, the front field part 171 may have the same crystal structure as the semiconductor substrate 110.

As an example, when the semiconductor substrate 110 is formed of a single crystal silicon material, the front field part 171 may also be formed of a single crystal silicon material.

The rear field part 172 is positioned on the rear surface of the semiconductor substrate 110 and extends in parallel with the second conductivity type region 120 positioned on the rear surface of the semiconductor substrate 110. The rear field part 172 may be doped with a dopant of the same conductivity type as that of the semiconductor substrate 110 at a higher concentration than a doping concentration of the semiconductor substrate 110.

As an example, the rear field part 172 may be formed in direct contact with the rear surface of the control passivation layer 160 and may be spaced apart from the second conductivity type region 120.

The second conductivity type region 120 is positioned on the rear surface of the semiconductor substrate 110 and extends in a direction parallel to the rear field part 172. The second conductivity type region 120 is doped with a dopant of a conductivity type opposite to the conductivity type of the semiconductor substrate 110. Therefore, the second conductivity type region 120 may form a p-n junction with the semiconductor substrate 110 with the control passivation layer 132 interposed therebetween, thus serving as an emitter part.

The intrinsic semiconductor part 190 may be disposed in a space between the rear field part 172 of the first conductivity type region 170 and the second conductivity type region 120 at a region on the rear surface of the control passivation layer 132 and may not include a first conductivity type dopant or a second conductivity type dopant.

The rear field part 172, the second conductivity type region 120, and the intrinsic semiconductor part 190 positioned on the control passivation layer 132 may be formed of a silicon material having a crystal structure different from that of a silicon material of the semiconductor substrate 110.

For example, when the semiconductor substrate 110 is formed of single crystal silicon, the rear field part 172, the second conductivity type region 120, and the intrinsic semiconductor part 190 may be formed of polycrystalline silicon or a mixture of polycrystalline silicon and amorphous silicon.

The insulating layer 130 may be positioned on at least one of one surface or the opposite surface of the semiconductor substrate 110. For example, as illustrated in FIG. 1, the insulating layer 130 may be positioned on the front surface of the semiconductor substrate 110. However, the present disclosure is not limited to FIG. 1, and in the case of a bifacial light receiving type photovoltaic solar cell, the insulating layer 130 may be further positioned on the rear surface which is the opposite surface of the semiconductor substrate 110.

As illustrated in FIG. 1, when the conductivity type region such as the front field part 171 is provided on the front surface of the semiconductor substrate 110, the insulating layer 130 may be positioned on the front field part 171. However, unlike FIG. 1, when the front field part 171 is not provided, the insulating layer 130 may be positioned in direct contact with the front surface of the semiconductor substrate 110.

Here, one surface of the semiconductor substrate 110 may be a front surface of a solar cell on which light is directly incident at the semiconductor substrate 110, and the opposite surface of the semiconductor substrate 110 may be a surface positioned opposite to the one surface of the semiconductor substrate 110, which may be a rear surface of the solar cell on which reflected light is incident.

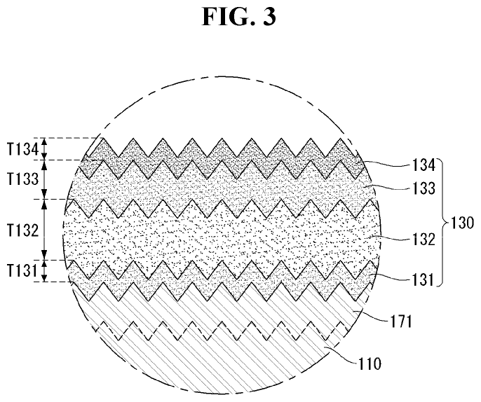

As illustrated in FIG. 1, the insulating layer 130 may include a first layer 131, a second layer 132, an anti-reflective layer 133, and a third layer 134. Details of each layer of the insulating layer 130 will be described below with reference to FIG. 3.

The insulating layer 130 minimizes reflectivity of light incident on the semiconductor substrate 110 from the outside, blocks ultraviolet (UV) rays incident on the semiconductor substrate 110 from the outside, suppresses etching due to an acetic acid generated from a sealing material such as an ethylene-vinyl acetate copolymer (EVA), one of the components of a solar cell module due to moisture penetration, and prevents carriers generated from the substrate are destroyed by the ultraviolet (UV) rays to improve an open circuit voltage (Voc) and a short circuit current (Isc) to improve the solar cell module, thereby generally improving efficiency of the solar cell module.

The plurality of first electrodes 140 may be connected to the second conductivity type region 120 and may be formed to elongate. The first electrode 140 may collect carriers moved toward the second conductivity type region 120.

The plurality of second electrodes 150 may be connected to the rear field part 172 of the first conductivity type region 170 and may elongate in parallel with the first electrode 140. The second electrode 150 may collect carriers moved toward the first conductivity type region 170.

The rear passivation layer 180 may be formed in regions excluding regions where the first and second electrodes 140 and 150 are formed in the entire rear surface region of the rear field part 172, the second conductivity type region 120, and the intrinsic semiconductor part 190.

The rear passivation layer 180 may remove a defect due to dangling bonds formed on the rear surface of the second conductivity type region 120, the first conductivity type region 170, and the intrinsic semiconductor part 190 each formed of polycrystalline silicon to prevent the carriers generated from the semiconductor substrate 110 from being recombined and dissipated by the dangling bonds.

The solar cell applied to the solar cell module according to the present disclosure is not limited to FIG. 1, and other components, except that the first and second electrodes 140 and 150 provided in the solar cell are formed only on the rear surface of the semiconductor substrate 110, may be changed as necessary.

For example, in FIG. 1, the front field part 171 of the first conductivity type region 170 may be omitted. In this case, the insulating layer 130 may be positioned in direct contact with the front surface of the semiconductor substrate 110.

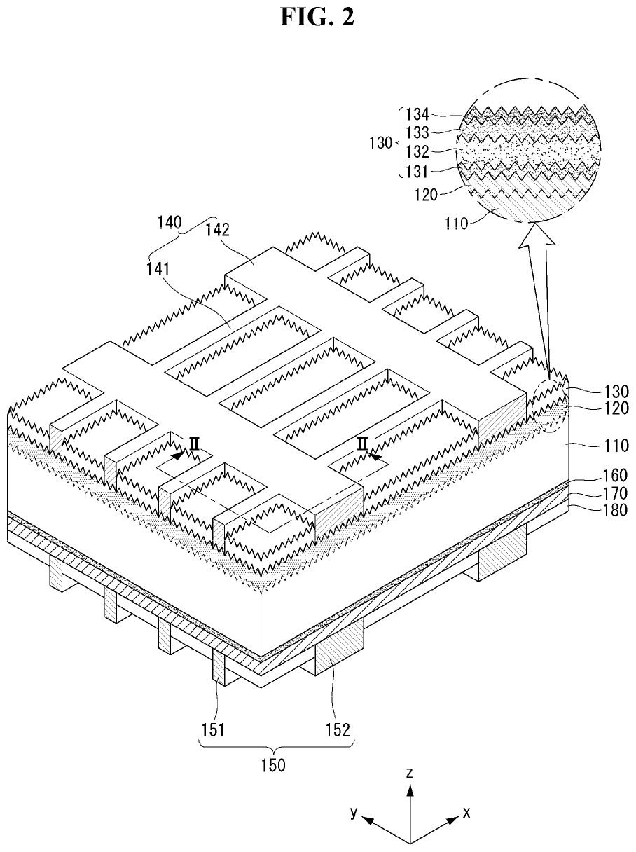

FIG. 2 is a view illustrating an example of a conventional type solar cell including an insulating layer 130 according to the first embodiment of the present disclosure.

In FIG. 2, a description of same parts as those in FIG. 1 will be replaced with the description of FIG. 1 and omitted in FIG. 2.

As illustrated in FIG. 2, an example of the conventional type solar cell including the insulating layer 130 according to a first embodiment of the present disclosure may include a semiconductor substrate 110, a control passivation layer 160, a first conductivity type region 170, a second conductivity type region 120, an insulating layer 130, a rear passivation layer 180, a first electrode 140, and a second electrode 150 may be provided.

The second conductivity type region 120 may be positioned on the front surface of the semiconductor substrate 110, and a first conductivity type dopant may be formed to be spread in the front surface of the semiconductor substrate 110. Therefore, the second conductivity type region 120 may have the same crystal structure as the semiconductor substrate 110 and may be formed of the same silicon material as the silicon material of the semiconductor substrate 110. For example, when the semiconductor substrate 110 is formed of a single crystal silicon material, the second conductivity type region 120 may also be formed of a single crystal silicon material.

The first conductivity type region 170 may be entirely positioned on the control passivation layer 132 formed on the rear surface of the semiconductor substrate 110. The first conductivity type region 170 may have a crystal structure different from that of the semiconductor substrate 110 and may be formed of a silicon material different from the silicon material of the semiconductor substrate 110. For example, when the semiconductor substrate 110 is formed of a single crystal silicon material, the first conductivity type region 170 may be formed of polycrystalline silicon or a mixture of polycrystalline silicon and amorphous silicon.

The first electrode 140 may include a plurality of first finger electrodes 141 extending in a first direction x and a plurality of first connection electrodes 142 extending in a second direction y. The second electrode 150 may include a plurality of second finger electrodes 151 extending in the first direction x and a plurality of second connection electrodes 152 extending in the second direction y.

The insulating layer 130 may be positioned on the second conductivity type region 120 formed in the front surface of the semiconductor substrate 110. As shown in FIG. 1, the insulating layer 130 may include a first layer 131, a second layer 132, an anti-reflective layer 133, and a third layer 134.

In addition, although not shown in FIG. 1, the insulating layer 130 may be positioned on the rear surface of the semiconductor substrate 110.

For example, the insulating layer 130 may be provided instead of the rear passivation layer 180 on the first conductivity type region 170 positioned on the rear surface of the semiconductor substrate 110.

In addition, in FIG. 2, a case where the second conductivity type region 120 is positioned on the front surface of the semiconductor substrate 110 and the first conductivity type region 170 is positioned on the rear surface of the semiconductor substrate 110 is described as an example, but the present disclosure is not limited thereto and the first conductivity type region 170 may be positioned on the front surface of the semiconductor substrate 110 and the second conductivity type region 120 may be positioned on the rear surface of the semiconductor substrate 110.

Hereinafter, the insulating layer 130 according to the first embodiment of the present disclosure will be described.

FIG. 3 is a view specifically illustrating a structure of the insulating layer 130 according to the first embodiment of the present disclosure.

The insulating layer 130 according to the first embodiment of the present disclosure is positioned on at least one of one surface or an opposite surface of the semiconductor substrate 110, and as illustrated in FIG. 3, when a conductivity type region, i.e., a front field part 171, is positioned on the semiconductor layer 110, the insulating layer 130 may be positioned on the front field part 171.

The insulating layer 130 minimizes reflectivity of light incident on the semiconductor substrate 110 from the outside, blocks ultraviolet (UV) rays incident on the semiconductor substrate 110 from the outside, suppresses etching due to an acetic acid generated from a sealing material such as an ethylene-vinyl acetate copolymer (EVA), one of the components of a solar cell module due to moisture penetration, and prevents carriers generated from the substrate are lost by the ultraviolet (UV) rays to improve an open circuit voltage (Voc) and a short circuit current (Isc) to improve the solar cell module, thereby generally improving efficiency of the solar cell module.

To this end, as shown in FIG. 3, the insulating layer 130 according to the first embodiment may include a first layer 131, a second layer 132, an anti-reflective layer 133, and a third layer 134 sequentially stacked on the semiconductor substrate 110.

Accordingly, the first layer 131 is positioned closest to the semiconductor substrate 110 among the plurality of layers forming the insulating layer 130, and the third layer 134 may configure the outermost layer among the plurality of layers forming the insulating layer 130.

The first layer 131 is positioned closest to the semiconductor substrate 110 and is formed to have a high bandgap. Therefore, although carriers generated in the semiconductor substrate 110 are excited by UV rays incident from the outside, the excited carriers may be prevented from moving to the second layer 132 so as to be trapped in the second layer 132. Accordingly, the open circuit voltage Voc and the short circuit current Isc of the solar cell may be further improved.

That is, since the first layer 131 has a higher bandgap than other layers of the insulating layer 130, i.e., the second layer 132, the anti-reflective layer 133, and the third layer 134, although the carriers generated in the semiconductor substrate 110 are excited by UV rays, the first layer 131 may block the excited carriers from moving to the second layer 132 or the anti-reflective layer 133. Accordingly, the solar cell may be prevented from being degraded by the UV rays and lowered in efficiency, thereby being stabilized (saturated).

The bandgap of the first layer 131 may be higher than that of each of the second layer 132, the anti-reflective layer 133, and the third layer 134. For example, magnitude order of the bandgaps may be the first layer 131>the anti-reflective layer 133>the second layer 132>the third layer 134.

For example, the bandgap of the first layer 131 may be 8 eV to 10 eV, preferably, 8.6 eV to 9.1 eV, in a range higher than that of each of the second layer 132, the anti-reflective layer 133, and the third layer 134.

As described above, since the first layer 131 of the present disclosure is positioned between the outer surface of the semiconductor substrate 110 (or the outer surface of the conductivity type region) and the second layer 132 or the anti-reflective layer 133 having a bandgap lower than that of the first layer 131, although carriers generated in the semiconductor substrate 110 are excited by UV rays incident from the outside, the excited carriers cannot move to the second layer 132 or the anti-reflective layer 133 because the bandgap of the first layer 131 is high. Therefore, a phenomenon in which the excited carriers are trapped in the second layer 132 or the anti-reflective layer 133 is prevented.

In order for the first layer 131 to perform the above-described action, the first layer 131 may include an oxygen (O)-based material. For example, the first layer 131 may include SiOx, SiO2, SiOxNy, AlxOy, TixOy, or HfOx.

However, even a layer including at least one of SiOx, SiO2, SiOxNy, AlxOy, TixOy, or HfOx does not have a high bandgap only with at least one of the above materials.

That is, although a certain layer includes at least one of SiOx, SiO2, SiOxNy, AlxOy, TixOy, or HfOx, a bandgap of the layer may vary depending on a temperature, a composition of a process gas, a thickness of the layer, and a method of forming the layer.

The first layer 131 of the present disclosure may be formed (1) by thermal oxidation in a furnace, (2) by plasma enhanced chemical vapor deposition (PECVD), or (3) by mixing the above two methods.

Thus, although the certain layer includes at least one of SiOx, SiO2, SiOxNy, AlxOy, TixOy, or HfOx, it may have a bandgap completely different from the bandgap of the first layer 131 of the present disclosure and may perform a completely different function depending on a position and thickness.

The first layer 131 of the present disclosure may include the same material as that of the second layer 132 described above. However, although the first layer 1311 includes the same material as the second layer 132, the first layer 131 may be different in position and has a completely different thickness and bandgap, so that the first layer 131 may perform a function completely different from that of the second layer 132.

Specifically, in view of material properties, the second layer 132 may be formed in a heat treatment process at 600° C. to 700° C. so as to be formed as a low quality layer having a relatively low density compared to the first layer 131, while the first layer 131 may be formed in a heat treatment process at 850° C. so as to be formed as a high quality film that is relatively dense and harder than the second layer 132.

Accordingly, the first layer 131 has a higher bandgap than the second layer 132 so that a phenomenon in which the carriers generated in the semiconductor substrate 110 jump to move to the second layer 132 or the anti-reflective layer 133 positioned on the outer side of the semiconductor substrate 110 may be prevented.

As described above, the first layer 131 may be formed to include the same material as the second layer 132 but may be completely different in position, thickness, and material characteristics from the second layer 132 to perform a completely different function.

The second layer 132 may be positioned on an outer surface of the first layer 131, and a hydrogen content of the second layer 132 may be higher than a hydrogen content of each of the first layer 131, the anti-reflective layer 133, and the third layer.

Accordingly, hydrogen contained in the second layer 132 may pass through the first layer 131 and move toward the semiconductor substrate 110 during a manufacturing process of the insulating layer 130, and the transferred hydrogen may eliminate dangling bonds of the semiconductor substrate. Thus, the second layer 132 may perform a passivation function on the semiconductor substrate 110. This may increase the short circuit current Isc of the solar cell.

The second layer 132 may include a nitrogen (N)-based material or an oxygen (O)-based material in a silicon (Si) material. For example, the second layer 132 may be formed of a silicon nitride layer (SiNx) or aluminum oxide layer (Al₂O₃).

The anti-reflective layer 133 may be positioned on the outer surface of the second layer 132 to improve transmittance of light incident from the outside and prevent an out-diffusion phenomenon in which hydrogen of the second layer 132 is discharged out of the insulating layer 130 during the manufacturing process of the insulating layer 130.

Transmittance of the anti-reflective layer 133 for visible light (wavelength band of 400 nm to 1100 nm) may be higher than that of the second layer 132 and lower than that of the first layer 131. In addition, a refractive index of the anti-reflective layer 133 for visible light may be lower than that of the third layer 134 and the second layer 132 excluding the first layer 131 having a high bandgap.

The anti-reflective layer 133 may include an oxygen (O)-based or nitrogen (N)-based material in a silicon (Si) material. For example, the anti-reflective layer 133 may include at least one of SiOx, SiOxNy, or SixNy.

The third layer 134 may be formed on the outer surface of the anti-reflective layer 133 and include a silicon (Si)-based material and a carbon (C)-based material.

The silicon-based material included in the third layer 134 may absorb UV rays having a wavelength of 400 nm or less in a wavelength band of light. Therefore, UV rays may be blocked from being transmitted to the inside where the semiconductor substrate 110 is positioned from the outside of the insulating layer 130.

The carbon-based material included in the third layer 134 may prevent a phenomenon in which the insulating layer 130, in particular, the third layer 134, is etched by an acetic acid generated from a sealing material such as an EVA.

The third layer 134 may be formed of a material containing a silicon (Si)-based material and a carbon (C)-based material together, for example, at least one of SixOyCz, SixCy, or SixCyNz.

The refractive indices of the respective layers of the insulating layer 130 are compared as follows.

The refractive index of the third layer 134 may be higher than those of the second layer 132 and the first layer 131. For example, the refractive index of the third layer 134 may be 2.2 or greater. More preferably, in case where the insulating layer 130 is applied to the back contact type solar cell as shown in FIG. 1, the refractive index of the third layer 134 may be formed to be 2.6 to 2.7.

The refractive index of the second layer 132 may be higher than the refractive index of the anti-reflective layer 133 and the refractive index of the first layer 131. For example, the refractive index of the second layer 132 may be formed to be 1.9 to 2.2. More preferably, when the insulating layer 130 is applied to the back contact type solar cell as shown in FIG. 1, the refractive index of the second layer 132 may be formed to be 2.0 to 2.1.

In addition, the refractive index of the anti-reflective layer 133 may be formed to be 1.9 or less. For example, when the insulating layer 130 is applied to the back contact type solar cell as shown in FIG. 1, the refractive index of the anti-reflective layer 133 may be formed to be 1.4 to 1.5.

In addition, the refractive index of the first layer 131 may be formed to be 1.4 to 1.5.

Therefore, in consideration of the refractive index of each layer of the insulating layer 130, the refractive index of the insulating layer 130 may decrease in order of the third layer 134>the second layer 132>the anti-reflective layer 133>the first layer 131. Accordingly, the insulating layer 130 may minimize reflectivity of light incident from the outside.

The refractive index of each layer in the insulating layer 130 may be related to the bandgap of each layer. Due to the refractive indices, the order of the bandgaps in the insulating layer 130 may be formed in reverse order of the refractive indices as described above.

Thicknesses of the respective layers of the insulating layer 130 are compared as follows.

A thickness T132 of the second layer 132 may be greater than the thickness of each of the first layer 131, the anti-reflective layer 133, and the third layer 134, and the thickness T134 of the third layer 134 may be smaller than the thickness of each of the first layer 131 and the anti-reflective layer 133.

For example, the thickness T132 of the second layer 132 may be 50 nm or less in a range larger than the thickness of each of the first layer 131, the anti-reflective layer 133, and the third layer 134. Specifically, the thickness T132 of the second layer 132 may be 30 nm to 50 nm.

The thickness T132 of the second layer 132 is greater than the thickness of each of the first layer 131, the anti-reflective layer 133, and the third layer 134 in order to sufficiently secure the content of hydrogen contained in the second layer 132 to sufficiently secure a passivation function of the insulating layer 130 with respect to the semiconductor substrate 110.

The thickness T134 of the third layer 134 may be, for example, 20 nm or less in a range smaller than the thickness of each of the first layer 131 and the anti-reflective layer 133, and more specifically, the thickness T134 of the third layer 134 may be 5 nm to 12 nm.

The thickness T131 of the first layer 131 may be, for example, 40 nm or less in a range equal to or less than the thickness T134 of the third layer 134 or larger than the thickness T134 of the third layer 134. Specifically, the thickness T131 of the first layer 131 may be 8 nm to 25 nm.

The thickness T133 of the anti-reflective layer 133 may be, for example, 40 nm or less in a range greater than the thickness T134 of the third layer 134 and smaller than the thickness T132 of the second layer 132, and specifically, the thickness T133 of the anti-reflective layer 133 may be 20 nm to 40 nm in a range larger than the thickness T134 of the third layer 134 and smaller than the thickness T132 of the second layer 132.

The thickness of each layer in the insulating layer 130 may be formed in a range different from those described above.

In FIGS. 1 to 3, the case where the first layer 131 is formed as a single layer is described as an example, but the first layer 131 may include a plurality of layers having different densities. This will be described in more detail as follows.

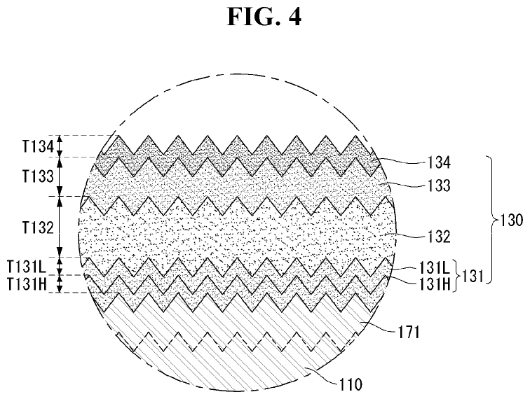

FIG. 4 is a view illustrating a structure of the insulating layer 130 according to a second embodiment of the present disclosure.

In FIG. 4, a description of the same part as that of FIG. 3 will be replaced with the description of FIG. 3, and different parts will be mainly described.

As illustrated in FIG. 4, the first layer 131 of the insulating layer 130 according to the second embodiment of the present disclosure may include a high density layer 131H and a low density layer 131L.

The high density layer 131H may be positioned adjacent to the semiconductor substrate 110 and have a first density, and the low density layer 131L may be positioned on the high density layer 131H and have a second density lower than the first density.

Here, the high density layer 131H may include SiO₂ as an example, and the low density layer 131L may include SiOx as an example. However, the present disclosure is not limited thereto. As another example, the high density layer 131H may include SiO₂, and the low density layer 131L may include SiOxNy.

As described above, when the first layer 131 includes the high density layer 131H and the low density layer 131L, the thickness T131 of the first layer 131 may be greater compared to the insulating layer shown in FIG. 3. Therefore, compared with the insulating layer shown in FIG. 3, the bandgap of the first layer 131 may be further increased, so that although the carriers generated in the semiconductor substrate 110 are excited by UV light, the excited carriers may be reliably effectively prevented from jumping the bandgap of the first layer 131 to move to the second layer 132 or the anti-reflective layer 133 and the open voltage (Voc) of the solar cell may be further improved.

When the thickness T131 of the first layer 131 is small, a desired bandgap may not be secured. However, as the thickness of the first layer 131 increases, the bandgap increases. Therefore, when the first layer 131 is formed of the high density layer 131H and the low density layer 131L to increase the thickness T131 of the first layer 131 compared to the embodiment of FIG. 3, although the amount of excited carriers is increased, it is possible to more reliably block the movement of the excited carriers to the second layer 132 or the anti-reflective layer 133 by jumping the bandgap of the first layer 131. Therefore, it is possible to prevent the insulation layer 130 from being degraded by UV rays.

In addition, when the first layer 131 is formed of only one layer, the passivation function of the semiconductor substrate 110 may be relatively reduced. However, when the first layer 131 includes the high density layer 131H and the low density layer 131L as in the second embodiment, high-quality passivation performance may be obtained, while degradation by ultraviolet (UV) as described above is prevented.

If the first layer 131 is formed of a plurality of layers and include the high density layer 131H and the low density layer 131L, a manufacturing time for the first layer 131 may be relatively shortened as compared with a case where the first layer 131 is formed thick only with one high density layer, and stability of the first layer 131 may be further increased.

That is, the high density layer 131H may be formed in a furnace by a thermal oxidation method, and since a layer is formed in a relatively high temperature heat treatment state according to the thermal oxidation method as compared with a method of forming the low density layer 131L, a growth rate of the layer is relatively low compared to the method of forming the low density layer. However, the high density layer may be formed with a first density which is relatively high compared to the low density layer, and thus, stability of the layer may be high.

The low density layer 131L may be formed by PECVD. According to PECVD, a layer is formed in a relatively low temperature heat treatment state as compared with the method of forming the high density layer 131H, and thus, a growth rate of the layer is relatively fast compared to the method of forming the high density layer. However, the low density layer 131L may be formed with a second density relatively lower than the first density of the high density layer 131H.

As described above, when the first layer 131 includes the high density layer 131 H and the low density layer 131L, stability of the first layer 131 may be sufficiently secured, while the function of the first layer 131 is strengthened and a manufacturing time may be shortened as compared with a case where the first layer 131 is formed only of a high density layer.

That is, when the first layer 131 is formed thick only with the high density layer 131H, the function and stability of the first layer 131 may be sufficiently secured but a process time for manufacturing the first layer 131 may be excessively lengthened.

In addition, when the first layer 131 is formed thick with only the low density layer 131L, the process time for manufacturing the first layer 131 may be shortened but the function of the first layer 131 may be relatively low to degrade efficiency of the solar cell.

In view of this, in the present disclosure, the first layer 131 is formed of the high density layer 131H and the low density layer 131L, thereby further enhancing the function of the first layer 131, sufficiently securing the stability of the first layer 131, and the manufacturing time may be shortened as compared with the case where the first layer 131 is formed thick only with a high density layer.

In addition, the reason why the high density layer 131H is formed closer to the semiconductor substrate 110 than the low density layer 131L is that the function of the first layer 131 may be sufficiently exhibited and stability of the first layer 131 may be further enhanced when the high density layer 131H having a relatively higher density than the low density layer 131L is closer to the semiconductor substrate, and by allowing the low density layer 131L formed by PECVD to be positioned on the high density layer, a follow-up process for the second layer 132 formed by PECVD may be easily performed to facilitate the manufacturing process of the insulating layer 130 and shorten an overall manufacturing time for the manufacturing process of the insulating layer 130.

In addition, after the low density layer 131L is formed by PECVD, the second layer 132 having a high hydrogen content may be formed on the low density layer 131L. In this case, during the process of forming the second layer 132, a portion of the large amount of hydrogen contained in the second layer 132 may move toward the semiconductor substrate 110 through the first layer 131 to form a silicon-hydrogen (Si—H) bond at a portion of the semiconductor substrate 110 where a defect is formed, thereby eliminating the defect of the semiconductor substrate 110. Therefore, the semiconductor substrate 110 may be effectively passivated.

An annealing process may be performed during the process of forming the second layer 132, and the silicon-hydrogen (Si—H) bond may be broken during the annealing process and the broken hydrogen (H) may be out-diffused in a direction opposite to the semiconductor substrate 110. In this case, the low density layer 131L formed by PECVD may prevent out-diffusion of hydrogen (H).

As described above, according to the present disclosure, the first layer 131 is formed of the high density layer 131H and the low density layer 131L, thereby further simplifying the manufacturing method, while further improving the efficiency of the solar cell.

Here, the thickness T131 of the first layer 131 including the high density layer 131H and the low density layer 131L may be, for example, 40 nm or less within a range greater than the thickness T134 of the third layer 134 and smaller than the thickness T132 of the second layer, and specifically, the thickness T131 of the first layer 131 including the high density layer 131H and the low density layer 131L may be 8 nm to 25 nm.

The thickness T131H of the high density layer 131H may be 5 nm to 10 nm, for example, 5 nm to 7 nm, and the thickness T131 L of the low density layer 131 L may be 2 nm to 15 nm, and for example, 5 nm to 13 nm.

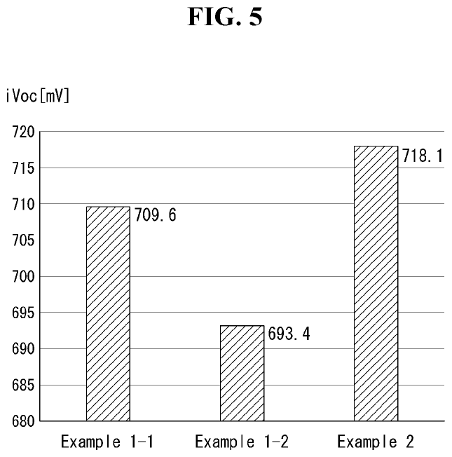

FIG. 5 is a view illustrating a comparison between a passivation effect of the insulating layer 130 according to the first embodiment and a passivation effect of the insulating layer 130 according to the second embodiment of the present disclosure.

The graph shown in FIG. 5 shows the comparison by simulating estimated open circuit voltages (implied-Voc, iVoc) of the solar cell in order to confirm the passivation effect of the insulating layer 130 according to an embodiment of the present disclosure.

Here, Example 1-1 shows an estimated open circuit voltage iVoc in case where the first layer 131 is formed of a single layer in a furnace using the thermal oxidation method, as the insulating layer 130 according to the first embodiment. Example 1-2 shows an estimated open circuit voltage iVoc in case where the first layer 131 is formed of a single layer using PECVD. Example 2 shows an estimated open circuit voltage iVoc in case where the first layer 131 includes the high density layer 131H using the thermal oxidation method and the low density layer 131L using PECVD, as the insulating layer 130 according to the second embodiment illustrated in FIG. 4.

Referring to FIG. 5, it can be seen that the estimated open circuit voltage of the case of Example 2 is higher than those of Example 1-1 and Example 1-2.

Accordingly, it can be seen that the first layer 131 according to the second embodiment of the present disclosure has a better function than the first layer 131 according to the first embodiment of the present disclosure.

In addition, it can be seen that the passivation function of the first layer 131 according to the second embodiment of the present disclosure is better than that of the first layer 131 according to the first embodiment of the present disclosure.

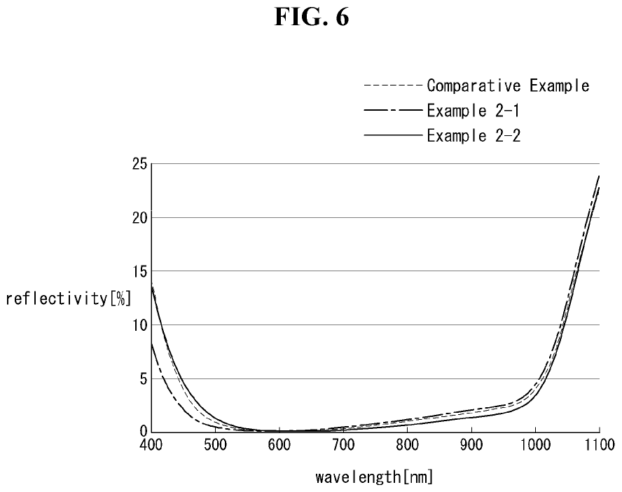

FIG. 6 is a view illustrating a reflectance of the insulating layer 130 according to the second embodiment of the present disclosure.

In FIG. 6, unlike Examples 1 and 2, reflectivity of Comparative Example was obtained in case where stacking order of the anti-reflective layer 133 and the second layer 132 in the insulating layer 130 are reversed (i.e., the insulating layer 130 includes the first layer 131, the anti-reflective layer 133, the second layer 132, and the third layer 134 formed from the semiconductor substrate 110). Reflectivity of Example 2-1 was obtained in case where the high density layer 131H of the first layer 131 was 6 nm and the low density layer 131L was 5 nm in the second embodiment of the present disclosure. Also, reflectivity of Example 2-2 was obtained in case where the high density layer 131H of the first layer 131 was 6 nm and the low density layer 131L was 10 nm in the second embodiment of the present disclosure.

In the case of Example 2-1, it can be seen that reflectivity is better than Comparative example in a wavelength range of 400 nm to 600 nm of visible light and is similar to that of Comparative Example in the remaining wavelength range of 600 nm to 1100 nm.

In the case of Example 2-2, it can be seen that reflectivity is maintained to be similar to that of Comparative Example in the range of 400 nm to 600 nm and is better than that of Comparative Example in the range of 600 nm to 1100 nm.

As described above, it can be confirmed that the insulating layer 130 according to the second embodiment has overall reflectivity better than that of Comparative Example.

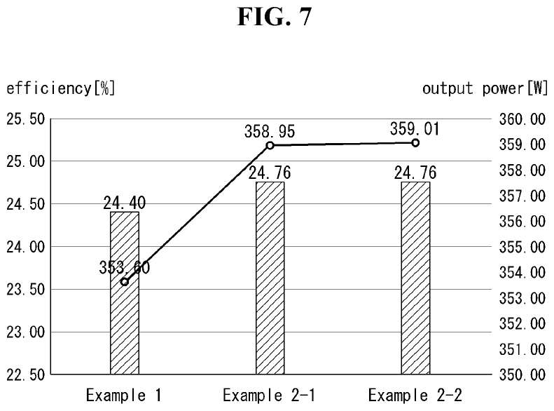

FIG. 7 is a view illustrating output power and efficiency of the solar cell including the insulating layer 130 according to the second embodiment of the present disclosure.

FIG. 7 is a graph showing a comparison between efficiency and output power according to Example 1 and Example 2 of the insulating layer 130 of the present disclosure.

Here, Example 1 illustrates efficiency and output power of a solar cell in which the first layer 131 of the insulating layer 130 illustrated in FIG. 3 was formed to have a thickness of 6 nm by the thermal oxidation method. Example 2-1 shows efficiency and output power of a solar cell in which the high density layer 131H of the first layer 131 of the insulating layer 130 illustrated in FIG. 4 was formed to have a thickness of 6 nm and the low density layer 131L was formed to have a thickness of 5 nm. Example 2-2 illustrates efficiency and output power of a solar cell in which the high density layer 131H of the first layer 131 of the insulating layer 130 shown in FIG. 4 was formed to have a thickness of 6 nm and the low density layer 131L was formed to have a thickness of 10 nm.

As shown in FIG. 7, it can be seen that Example 1 had relatively low efficiency and output power as compared with Example 2-1 and Example 2-2, Example 2-1 and Example 2-2 had efficiency and output power higher than Example 1, and a numerical change between Example 2-1 and Example 2-2 is insignificant.

As described above, it can be confirmed that when the efficiency of the solar cell is improved overall when the first layer 131 includes the mixture of the high density layer 131H and the low density layer 131L, as compared with the case where the first layer 131 is formed as one layer.

So far, only the structure of the insulating layer 130 according to the first and second embodiments of the present disclosure has been described. Hereinafter, a method of forming the insulating layer 130 will be described.

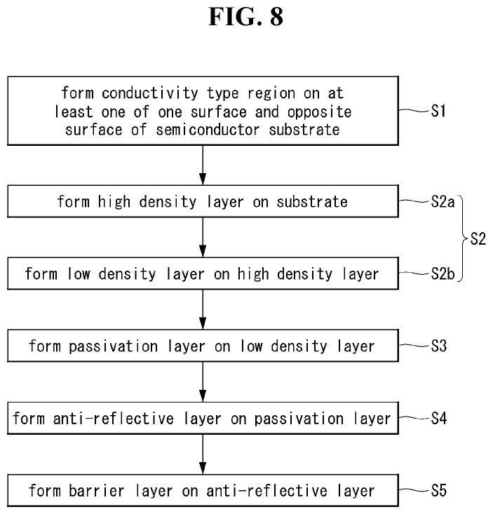

FIG. 8 is a view illustrating a method of manufacturing a solar cell according to an embodiment of the present disclosure.

In FIG. 8, a method of forming the insulating layer 130 in the solar cell manufacturing method according to an embodiment of the present disclosure will be described, but the method of forming the insulating layer 130 according to the second embodiment of the present disclosure will be described as an example.

As illustrated in FIG. 8, the solar cell manufacturing method according to an embodiment of the present disclosure may include a conductivity type region forming step (S1) and insulating layer forming steps (S2+S3+S4+S5), and the insulating layer forming steps S2+S3+S4+S5 may include a first layer forming step S2, a second layer forming step S3, an anti-reflective layer forming step S4, and a third layer forming step S5.

When the insulating layer 130 is formed on the semiconductor substrate 110, if a conductivity type region is positioned inside or on the surface of the semiconductor substrate 110, the insulating layer 130 may be formed on the conductivity type region.

In the conductivity type region forming step S1, a conductivity type region may be formed on at least one of one surface or the opposite surface of the semiconductor substrate 110.

The conductivity type region forming step S1 is applicable only when the conductivity type region is formed at a portion of the surface of the semiconductor substrate 110 where the insulating layer 130 is to be formed, and the conductivity type region forming step S1 may be omitted in case where the conductivity type region is not formed on the surface of the semiconductor substrate 110 where the insulating layer 130 is to be formed.

For example, as shown in FIGS. 1 and 2, when the conductivity type region is formed on the surface of the semiconductor substrate 110 on which the insulating layer 130 is formed, the insulating layer may be formed in the insulating layer forming steps (S2+S3+S4+S5) after the conductivity type region is formed, and if the front field part 171 is omitted at the front surface of the semiconductor substrate 110 shown in FIG. 1, the insulating layer may be directly formed on the front surface of the semiconductor substrate 110 in the insulating layer forming steps (S2+S3+S4+S5). In this case, the conductivity type region forming step S1 may be omitted.

As described above, the insulating layer forming steps S2+S3+S4+S5 may include the first layer forming step S2, the second layer forming step S3, the anti-reflective layer forming step S4, and the third layer forming step S5.

In the first layer forming step S2, the first layer 131 including an oxygen (O)-based material may be formed on the semiconductor substrate 110. When the conductivity type region is already formed at the semiconductor substrate 110, the first layer 131 may be formed on the conductivity type region. If the conductivity type region does not need to be provided at the region of the semiconductor substate 110 in which the first layer 131 is to be formed, the first layer 131 may be directly formed on the surface of the semiconductor substrate 110.

The first layer forming step S2 may be performed at a heat treatment temperature of 850° C. or higher, and the first layer may be formed to have a thickness of 40 nm or less.

The first layer forming step S2 may include a high density layer forming step S2a and a low density layer forming step S2b.

In the high density layer forming step S2a, the high density layer 131H having a first density may be formed on the semiconductor substrate 110 by a thermal oxidation method.

When the conductivity type region is provided on the semiconductor substrate 110, the high density layer 131 H may be formed on the conductivity type region. When the conductivity type region is not provided, the high density layer 131H may be directly formed on the surface of the semiconductor substrate 110.

In the low density layer forming step S2b, the low density layer 131L having a second density lower than the first density of the high density layer 131H may be formed on the high density layer 131H by PECVD.

Here, the high density layer forming step (S2a) and the low density layer forming step (S2b) are not essential, and either of the high density layer forming step S2a or the low density layer forming step S2b may be provided. However, when both the high density layer forming step S2a and the low density layer forming step S2b are provided, the efficiency of the solar cell may be further improved, and thus, the case where the both are provided will be described as an example.

Subsequently, in the second layer forming step S3, the second layer 132 may be formed on the low density layer 131L of the first layer 131. The second layer 132 may be formed by PECVD.

Thereafter, in the anti-reflective layer forming step S4, the anti-reflective layer 133 may be formed on the second layer 132. The anti-reflective layer 133 may be formed by PECVD.

Subsequently, in the third layer forming step S5, the third layer including a silicon (Si)-based material and a carbon (C)-based material may be formed on the anti-reflective layer 133. The third layer 134 may be formed by PECVD.

The case where the third layer 134, the anti-reflective layer 133, the second layer 132, and the low density layer 131L of the first layer 131 are each formed by PECVD is described as an example, but each of the third layer 134, the anti-reflective layer 133, the second layer 132, and low density layer 131L of the first layer 131 may be formed by a different type CVD, excluding the PECVD.

As described above, in the solar cell according to the present disclosure, the insulating layer includes the first layer, the second layer, the anti-reflective layer, and the third layer, UV rays are blocked and etching of the insulating layer due to an acetic acid is prevented using the third layer, and a phenomenon in which carriers generated in the substrate are destroyed by UV rays is prevented using the first layer, whereby efficiency of the solar cell may be further improved.

The features, structures, effects, and the like described in the above-described embodiments include at least one embodiment of the present disclosure, but the present disclosure is not limited only to one embodiment. Further, the features, structures, effects, and the like illustrated in each embodiment may be combined or modified to other embodiments by those skilled in the art. Therefore, contents related to the combination or the modification should be interpreted to be included in the scope of the disclosure.

What is claimed is:

1. A solar cell comprising:
a semiconductor substrate;
a conductivity type region positioned at or on the semiconductor substrate and including impurities;
an electrode electrically connected to the conductivity type region; and
an insulating layer positioned on at least one of one surface or the opposite surface of the semiconductor substrate,
wherein the insulating layer comprises:
a first layer positioned on the semiconductor substrate and including an oxygen (O)-based material;
a second layer positioned on the first layer;
an anti-reflective layer positioned on the second layer; and
a third layer positioned on the anti-reflective layer and including a silicon (Si)-based material and a carbon (C)-based material,
wherein a bandgap of the first layer is higher than a bandgap of each of the second layer, the anti-reflective layer, and the third layer.

2. The solar cell of claim 1, wherein the conductivity type region is positioned on at least one of the one surface and the opposite surface of the semiconductor substrate, and the first layer is positioned on the conductivity type region.

3. The solar cell of claim 1, wherein the bandgap of the first layer is 8 eV to 10 eV within a range higher than the bandgap of each of the second layer, the anti-reflective layer, and the third layer.

4. The solar cell of claim 1, wherein the first layer includes at least one of SiOx, SiO₂, SiOxNy, AlxOy, TixOy, or HfOx.

5. The solar cell of claim 1, wherein the second layer contains hydrogen, and a hydrogen content of the second layer is higher than a hydrogen content of each of the first layer, the anti-reflective layer, and the third layer.

6. The solar cell of claim 1, wherein the second layer includes a silicon (Si)-based material and further includes a nitrogen (N)-based material or an oxygen (O)-based material.

7. The solar cell of claim 6, wherein the second layer includes SiNx or AlxOy.

8. The solar cell of claim 1, wherein the anti-reflective layer includes a silicon (Si)-based material and further includes an oxygen (O)-based or nitrogen (N)-based material.

9. The solar cell of claim 8, wherein the anti-reflective layer includes at least one of materials among SiOx, SiOxNy, and SixNy.

10. The solar cell of claim 1, wherein transmittance of the anti-reflective layer for a wavelength band of 400 nm to 1100 nm is higher than transmittance of the second layer for the wavelength band and lower than transmittance of the first layer for the wavelength band.

11. The solar cell of claim 1, wherein the third layer includes at least one of materials among SixOyCz, SixCy, and SixCyNz.

12. The solar cell of claim 1, wherein a refractive index of the third layer is higher than a refractive index of the second layer and a refractive index of the first layer and is 2.2 or greater, the refractive index of the second layer is higher than the refractive index of the anti-reflective layer and the refractive index of the first layer and is 1.9 to 2.2, and the refractive index of the anti-reflective layer is 1.9 or less.

13. The solar cell of claim 1, wherein a thickness of the second layer is greater than a thickness of each of the first layer, the anti-reflective layer, and the third layer and is 50 nm or less, the thickness of the third layer is smaller than the thickness of the first layer and the thickness of the anti-reflective layer and is 20 nm or less, and the thickness of the first layer is greater than the thickness of the third layer and is 8 nm to 25 nm.

14. The solar cell of claim 1, wherein the first layer comprises a high density layer positioned adjacent to the substrate and having a first density and a low density layer positioned on the high density layer and having a second density lower than the first density, and
wherein the high density layer includes SiO₂ and the low density layer includes SiOxNy.

15. The solar cell of claim 14, wherein a thickness of the high density layer is 5 nm to 10 nm, and a thickness of the low density layer is 2 nm to 15 nm.

16. The solar cell of claim 1, wherein the first layer in the insulating layer is positioned closest to the semiconductor substrate, and the third layer configures an outermost layer in the insulating layer.

17. The solar cell of claim 1, wherein the conductivity type region includes first and second conductivity type regions positioned adjacent to a rear surface of the semiconductor substrate and having different conductivity types, respectively, and the insulating layer is positioned on a front surface of the semiconductor substrate.

18. A method of manufacturing a solar cell, the method comprising:
forming a first layer including an oxygen (O)-based material on a semiconductor substrate;
forming a second layer on the first layer;
forming an anti-reflective layer on the second layer; and
forming a third layer including a silicon (Si)-based material and a carbon (C)-based material on the anti-reflective layer.

19. The method of claim 18, wherein
the forming of the first layer comprises:
forming a high density layer on the semiconductor substrate using an oxidation method; and
forming a low density layer having a density lower than the high density layer on the high density layer using plasma-enhanced chemical vapor deposition (PECVD).

20. The method of claim 19, wherein each of the third layer, the anti-reflective layer, and the second layer is formed by PECVD.
